(19) United States
(12) Patent Application Publication
(10) Pub. No.: US 2016/0042987 A1
(43) Pub. Date: Feb. 11, 2016

(54) FLEXIBLE HANDLING SYSTEM FOR SEMICONDUCTOR SUBSTRATES

(71) Applicant: RUDOLPH TECHNOLOGIES, INC., Flanders, NJ (US)

(72) Inventor: Dennis Benson, Burnsville, MN (US)

(73) Assignee: RUDOLPH TECHNOLOGIES, INC., Flanders, NJ (US)

(21) Appl. No.: 14/775,133

(22) PCT Filed: Mar. 17, 2014
(86) PCT No.: PCT/US14/30224

§ 371 Date: Sep. 11, 2015

Related U.S. Application Data
(60) Provisional application No. 61/799,726, filed on Mar. 15, 2013.

(51) Int. Cl. H01L 21/683

(52) U.S. Cl. CPC H01L 21/6838

(57) ABSTRACT

A member that facilitates the handling of semiconductor devices of arbitrary shapes and sizes by handling equipment not normally adapted to handling such devices is herein described. The member includes a base that emulates a substrate for which handling equipment is available. A fixation device on the base secures a device to the member. A vacuum structure allows a vacuum clamping system to simultaneously secure the member and a device to the handling equipment.

### TECHNICAL FIELD

The present invention relates to flexible automation and handling for semiconductor substrates during metrology, inspection and microfabrication steps of various types. Specifically, the present invention relates to a system and method for utilizing existing wafer handling equipment to transport and maneuver semiconductor devices and substrates that are not typically handled in an automated manner.

### BACKGROUND

When faced with a requirement for handling a substrate with a new shape, size or form factor, an initial question arises as to whether it may be necessary to design a new automation platform or methodology from scratch to accommodate the new substrate. The alternative is to determine a way to repurpose existing automation technologies for the new application. In most cases, it is most efficient to repurpose existing automation technologies to meet the needs of a new application. The difficult here is that existing technologies have in-build limitations that must be overcome while still satisfying the requirements of the new application.

There exist myriad structures for holding, transporting and fixturing workpieces. Examples relevant to the semiconductor industry include JEDEC trays, Auer boats, and film frame assemblies. Other examples include reconstituted eWLB substrates in which individual semiconductor devices are molded into a single reconstituted substrate. Of the foregoing examples, solutions such as JEDEC trays Auer boats and similar structures such as that described in U.S. Pat. No. 6,359,336, all appear to rely solely on mechanical means to positively locate a device/substrate. Further, these mechanisms all appear to require custom staging/top plates to handle disparately shaped devices. Film frames require that devices be adhered directly to the carrier film itself. While many devices may be placed on a film frame in a desired location/arrangement, removal requires costly and expensive equipment. While a film frame may be used in many different ways, the flexibility of the film itself can limit the uses of this form factor to only those devices small and/or light enough to not unduly deform the film. Film frames themselves are paradoxically not particularly flexible in their application. eWLB substrates reconstituted from individual devices embedded in a substrate are relatively easy to handle, but are very inflexible in their applications as well due to cost and the nature of the embedding/reconstitution process.

What appears to be needed therefore is a device handling mechanism and system that emulates existing film frame and/or other wafer handling form factors and requirements, which allows one to readily secure and remove devices, and which is sufficiently inexpensive to allow for a manufacturer to procure new mechanisms for handling new devices as the devices are modified. In particular, it would be desirable to deploy a mechanism for handling semiconductor devices and substrates that has quick release attachment capabilities that allow devices/substrates to be affixed to and removed from the carrier mechanism efficiently and safely. It would also be highly desirable if such a carrier mechanism could take advantage of existing staging/top plate vacuum systems to secure both the carrier mechanism and the devices affixed thereto to the top plate for imaging, measurement or processing.

### DESCRIPTION OF THE FIGURES

FIG. 1 is a schematic representation of one embodiment of a carrier.

FIG. 2 is a schematic representation of another embodiment of a carrier.

### DETAILED DESCRIPTION

The present invention involves a carrier 10 having a base 12 and a fixation mechanism 14. The base 12 of the carrier emulates selected semiconductor formats such as 200, 300, 450 mm, or other sized silicon wafers. The base 12 may also emulate film frames carriers or hoops of various sizes and shapes. Large format glass, silicon or composite panels of various shapes and sizes, such as, for example Generation 1-7, may also be emulated.

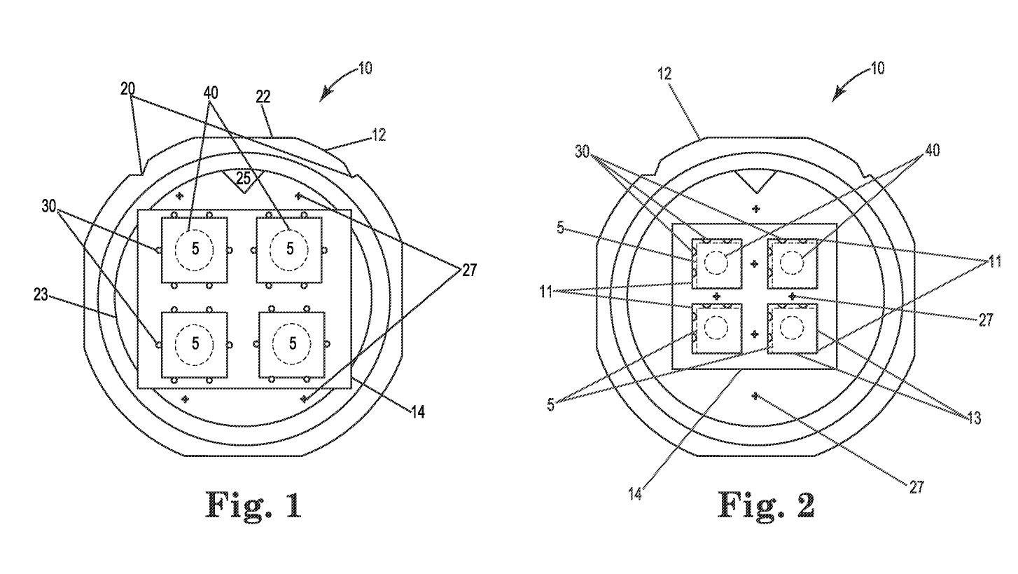

The base 12 of the carrier has dimensions and features that emulate those of selected substrate handling system, e.g. film frame, wafer or panel, among others. For example, one embodiment of the base 12 shown in FIG. 1 has a circular shape of a film frame as well as the alignment notches 20 of a film frame ring intended to engage alignment pins. This embodiment of the base 12 also has one or more flats 22 that assist in alignment of the base 12. In general however, the base 12 may have any selected set of features so long as the base 12 successfully emulates existing standards well enough to permit the use of existing automation equipment dedicated to the standard in question, i.e. where the carrier 10 is intended to emulate a film frame, the base 12 will have those features necessary for film frame handlers to reliable address and maneuver it. Preferably the base 10 will be made of a relatively rigid material. While a silicon wafer may be used as a base 10 in some embodiments, fiber composite materials such as carbon fiber may also be used. Composite materials of this type are rigid, tough and damp vibration, making them a good selection for a base 12. Other molded or machined materials such as PEEK (polyether ether ketone), nylon, polyoxymethylene (POM or DELRIN), aluminum and the like are also suitable.

Secured atop the base 12 is the fixation mechanism 14. The fixation mechanism 14 is adapted to secure to the carrier 10 semiconductor devices 5. In some embodiments physical detents 30 are provided to secure the semiconductor devices 5 to the carrier 10. These detents 30 resilient grip the sides of semiconductor devices 5. Pockets 11 (FIG. 2) having a shape at least slightly larger than and of a generally complementary geometry as the semiconductor devices may be provided to provide an additional holding and registration feature for the semiconductor devices. In any case, the fixation mechanism 14 is provided with at least one structure that acts to localize the semiconductor device on the carrier 10 without adhering the semiconductor device thereto. This facilitates easy automated pick and place of semiconductor devices or even manual loading.

Detents 30 may be of any useful form including springs of various shapes and types, simple protuberances that provide a gentle friction or force fit, clamps, or other mechanical devices. Note that detents 30 may be used to define pockets 11 in some embodiments. Preferably a fixation mechanism 14 may include a reference surface 13 against which each device 5 may be biased to ensure to some useful degree a known alignment. Such a reference surface may be defined by detents, springs, edges, or other mechanisms associated with the fixation mechanism, so long as the structure that defines the reference surface 13 is sufficiently rigid to define a substantially predictable position with respect to the remainder of the carrier 10.

The base 12 and fixation device 14 are provided with a vacuum assist structure 40 that permits handling equipment having vacuum control and clamping systems, such as in a top plate, stage or end effector, to secure both the carrier 10 and the semiconductor devices 5 for metrology, inspection or microfabrication processing. The vacuum assist structure may be a single bore positioned beneath each semiconductor device 5 as seen in FIGS. 1 and 2 or a series of holes or pores (e.g. a porous metallic or ceramic material) that allow vacuum systems in a top plate (not shown) to pull a vacuum between the semiconductor devices and top plate directly. An added benefit of the use of a hole as vacuum assist structure 40 such as that shown in the Figures is that this hole facilitates the manual removal of the semiconductor device from the carrier 10. Note that an important feature of a vacuum assist structure 40 as opposed to a simple aperture or gap is that a vacuum may be pulled and suitably maintained between semiconductor device 5 and the top plate, stage or end effector on which the carrier 10 is supported.

In another embodiment at least the base 12 of the carrier 10 may be formed of a semi porous material that will allow a vacuum to be pulled directly therethrough. In this way, no bores, pores or holes need be formed through the base 12 to facilitate vacuum clamping of the devices 5.

As will be appreciated, alignment of the semiconductor devices 5 to a metrology system, inspection system or microfabrication system is imperative. Accordingly, the detent 30 or reference surface 13 provides a first, coarse physical alignment of the semiconductor devices relative to the carrier 10. Next, the base 12 may provide physical alignment features such as notches 20 that provide another coarse physical alignment this time between the carrier 10 and the handling system or a top plate, stage or end effector thereof.

Another alignment step may take into consideration the geometry of the base 12 in much the same way that wafers and film frames are aligned. For example, the base 12 may be made of a single sheet of material such as a carbon fiber disk into which are formed the aforementioned notches 20 and flats 22. In addition to notches and flats, the base 12 may have formed therein a false edge 23 that represents the edge of a wafer. The edge may be formed by cutting away portions of the base 12, by etching the base, or by applying various high visibility materials such as a reflective Mylar, aluminum or the like. Similarly a false notch 25 or flat may be provided. In this way, inspection systems that are already pre-programed to locate a wafer or other substrate (which is being emulated) by its edge and/or by its notch or flat may use their existing programming to localize the carrier 10 to some degree.

Where a system that acts upon the semiconductor devices allows for the selection of fiducials or structures such as marks 27, such marks 27 may be used to obtain another type of alignment. The foregoing exemplary alignment routines may be used alone or together to obtain varying degrees of alignment between a semiconductor device 5 and a system that will act thereon. Often a system that acts on a semiconductor device will be provided with a means for optically aligning directly to the semiconductor device 5 itself to obtain an even finer alignment. In general, the carrier 10 is adapted to permit a first coarse, physical alignment between the carrier 10 and the handling system acting upon it and a second coarse, physical alignment between the carrier 10 and the semiconductor devices 5 mounted thereon. In this way the orientation of the semiconductor devices 5 mounted in the carrier 10 is rapidly accommodated to a pre-defined coordinate system of the handling system. Note that the coarse alignment process may involve physically moving the carrier 10 and the devices 5 mounted thereon relative to the handling system (e.g. by using alignment pins that engage notches 20 of base 12) or by moving the entire carrier 10 that is mounted on a top plate or stage relative to an inspection or metrology sensor or to a portion of process tool. Fiducials 27 on the base 12 and/or the fixation mechanism 14 may be used to conduct a fine, optical based alignment between the carrier 10 and the handling system and/or the system that will inspect, measure or act upon the semiconductor devices 5. Further, where the carrier 10 and its physical alignment mechanisms, working together with the handling system, are able to achieve an initial alignment of sufficient resolution, an inspection, metrology or process tool may directly address the semiconductor devices 5 without a second or fine alignment process. Many inspection, metrology and process tools that act upon semiconductor devices 5 are capable of working with a certain degree of alignment or mis-alignment without further

Where appropriate, fiducials 27 may be constructed and arranged as targets for optical calibration of alignment and inspection optics of a system that acts upon the devices 5.

In a preferred embodiment it is desirable to form the base 12 and the fixation mechanism 14 separate from one another. For example, one may form myriad different bases 12, all having the geometries required to emulate given handling systems, in advance of need. Thereafter, a suitable base 12 suited to a given handling system may be mated to a fixation device 14 that is specially adapted to physically secure and/or align devices 5 to the carrier. Alternatively, a unitary carrier 10 having an obviously or notionally distinct base 12 and fixation device 14 may be formed by machining, by molding or 3D printing. Where necessary, alignment and fiducial features such as edges 23, notches 25, and marks 27 may be added to the carrier 10.

Fixation mechanism 14 may be adapted to secure devices 5 to the carrier 10 in any suitable arrangement including rectilinear and curvilinear arrays. The nominal location of devices 5 in the fixation mechanism 14 may be noted relative to the various features of the base that may be used for alignment to provide a handy transform between the coordinate system of the base and that of the fixation mechanism. It may be useful to perform a detailed inspection of each carrier 10 prior to use to allow ensure that no defects are present and to also obtain relative positions of the various features of the base and fixation mechanism. In this way alignment is facilitated a priori.

The detailed inspection/measurement of the carrier 10 may be used to form a template that may be used to create “wafer maps” and “recipes” for actions that are to be performed on the devices 5. Wafer maps and recipes are concepts well known to those skilled in the art.

As part of the generation of a recipe and/or a wafer map, it is necessary to consider those ways in which the carrier does not emulate a particular substrate. For example, a carrier 10 with devices 5 secured thereto may by significantly thicker than a 300 mm wafer that the carrier 10 is emulating. In this case, it is necessary to consider whether a cassette in which the carriers 10 are to be stored can accept all of the carriers 10 whilst avoiding physical contact. Where a carrier is too thick or where it sags too much, it is possible that only every other slot (or fewer) of the cassette may be populated by a carrier. Similarly, it is necessary to double check all clearances in the system that is to act on the devices 5 to avoid contact damage between the carrier 10/devices 5 and the system.

Carriers 10 may be provided with identification indicia such as an alphanumeric code, a bar code, or QR code to allow the carrier to be tracked during the processing of the devices 5 and/or during its useful life. For example, it is a good idea to periodically inspect the carriers 10 to ensure that they remain uncontaminated and dimensionally acceptable. Identification indicia allow one to keep track of quality data relating to carrier 10 performance or problems over time. Further, pre-determined information such as nominal alignment information may be stored for a given carrier 10 and used to simplify recipe creation.

Although specific examples have been illustrated and described herein, a variety of alternate and/or equivalent implementations may be substituted for the specific examples shown and described without departing from the scope of the present disclosure. This application is intended to cover any adaptations or variations of the specific examples discussed herein. Therefore, it is intended that this disclosure be limited only by the claims and the equivalents thereof.

What is claimed is:

1. A carrier for one or more devices comprising:
a base constructed and arranged to emulate substrate that can be handled by an automated substrate handling system;
a fixation mechanism affixed to the base for securing to the base one or more of the devices;
at least one of the base and fixation mechanism being provided with a vacuum structure that communicates at least through the base to permit both the base and the one or more devices to be vacuum clamped to the automated substrate handling mechanism simultaneously.

2. The carrier of claim 1 further comprising:
an alignment structure formed into the base.

3. The carrier of claim 1 further comprising at least one fiducial mark formed into one of the base and the fixation mechanism.

4. The carrier of claim 1 further comprising a detent structure for securing a device to the carrier.

5. The carrier of claim 4 wherein the detent structure is selected from a group consisting of a friction fit device, a leaf spring, a spring loaded detent, and a clamp.

6. The carrier of claim 1 wherein the base substantially emulates a semiconductor wafer.

7. The carrier of claim 1 wherein the base substantially emulates a film frame.
